(19) United States
(12) Patent Application Publication
(10) Pub. No.: US 2013/0187676 A1
(43) Pub. Date: Jul. 25, 2013

(54) INSPECTION APPARATUS

(71) Applicants: Kenichi WASHIO, Musashino-shi (JP); Masashi HASEGAWA, Musashino-shi (JP)

(72) Inventors: Kenichi WASHIO, Musashino-shi (JP); Masashi HASEGAWA, Musashino-shi (JP)

(73) Assignee: KABUSHIKI KAISHA NIHON MICRONICS, Musashino-shi (JP)

(21) Appl. No.: 13/559,804

(22) Filed: Jul. 27, 2012

(30) Foreign Application Priority Data
Jan. 20, 2012 (JP) 2012-010294

(51) Int. Cl. G01R 31/26

(52) U.S. Cl. 324/756.03

(57) ABSTRACT

An inspection apparatus includes a probe card having a plurality of probes arranged to correspond to each chip of a semiconductor wafer under inspection and contacting a plurality of electrodes of each chip and a test head electrically connected to the respective probes of the probe card and applying test signals from a tester, and a plurality of tester lands of a probe substrate electrically connected respectively to the plurality of probes. A plurality of electrical connecting portions on the tester side of the test head, corresponding to the respective tester lands, are arranged to constitute a plurality of arrangement areas sectioned to correspond to the respective chips under inspection, and the plurality of probes of the probe substrate are connected to the corresponding tester lands provided in the arrangement areas in units of chips under inspection.

### CROSS-REFERENCE TO RELATED APPLICATION

This application claims, under 35 USC 119, priority of Japanese Application No. 2012-010294 filed on Jan. 20, 2012.

### BACKGROUND OF THE INVENTION

1. Technical Field Relating to the Invention

The present invention relates to an inspection apparatus in which electrical connection between a tester and a probe card for use in an electrical test of a device formed on a semiconductor wafer has been improved.

2. Description of Related Art

Electrical connection between a tester and a probe card of an inspection apparatus for use in an electrical test of a device formed on a semiconductor wafer is performed by tester connecting portions provided at the circumference of the probe card as described in Patent Document 1 (Japanese patent Laid-Open No. 2005-17121), for example. That is the tester connecting portions provided at the circumference of the probe card are electrically connected to the tester side, and inspection signals from the tester are applied via respective probes to respective electrodes of the device formed on the semiconductor for the test. Such a structure is however being improved since it complicates wiring for the electrical connection of the card substrate. An inspection apparatus improved in such a manner is a semiconductor inspection apparatus described in Patent Document 2 (Japanese patent Laid-Open No 2008-300481)

In this semiconductor inspection apparatus, a wiring board and an electrical connector arranged between a tester and a probe card are removed, and electrical connecting portions of the tester are connected directly to the probe card. A probe substrate of the probe card is provided on one surface with a plurality of probes to be brought into contact with respective electrodes of a device and on the other surface with a plurality of tester lands at positions corresponding to the electrical connecting portions on the tester side for connection to the tester. This simplifies connection between the electrical connecting portions on the tester side and the probe card and reduces effects of mutual noises among the wires due to shortening of the circuit length, which enables a higher frequency inspection.

Also, since the tester lands are arranged on the entire surface without being restricted by the outer circumferential portion of the probe substrate, the wire length can be further shortened.

### SUMMARY OF THE INVENTION

In the semiconductor inspection apparatus configured as above, connecting the electrical connecting portions on the tester side directly to the probe substrate of the probe card can simplify the configuration of the inspection apparatus and reduce cost of the members. The apparatus can also reduce effects of mutual noises among the wires due to shortening of the wire length from the tester to the probe substrate, which enables a higher frequency inspection.

However, in the above semiconductor inspection apparatus, since arrangement of signal, power, and ground wires connected from the tester circuit to the respective devices is determined with reference to the tester side as in a conventional case, internal wires from the tester lands on the upper surface of the probe substrate to the respective probes provided on the lower surface remain complicated. Accordingly, it is not easy for the respective wires in the probe substrate to be equal in length, which causes increase in design cost of the probe substrate.

The present invention is accomplished by taking such problems as mentioned above into consideration thereof, and an object thereof is to provide an inspection apparatus in which, in an inspection apparatus of a semiconductor wafer, connection between a tester and a probe card is configured with reference to positions of respective chips of the semiconductor wafer to simplify connection wiring in a probe substrate, facilitate wires of equal length, and reduce mutual noises among wires by shortening of the wire length, and to reduce design cost of the probe substrate.

An inspection apparatus according to the present invention at least comprises a probe card having a plurality of probes arranged to correspond to each chip under inspection of a semiconductor wafer and contacting a plurality of electrodes of each chip and a test head electrically connected to the respective probes of the probe card and applying test signals from a tester. In the inspection apparatus, a plurality of tester lands of a probe substrate electrically connected respectively to the plurality of probes and a plurality of electrical connecting portions on the tester side of the test head corresponding to the respective tester lands are arranged to constitute a plurality of arrangement areas sectioned to correspond to the respective chips under inspection, and the plurality of probes of the probe substrate are connected to the corresponding tester lands provided in the arrangement areas in units of chip under inspection.

With the above configuration, in an inspection apparatus for use in an electrical test of a device formed on a semiconductor wafer, connection wiring in a probe substrate can be simplified, wires of equal length are facilitated, mutual noises among wires are reduced by shortening of the wire length, and design cost of the probe substrate can be low.

### BRIEF DESCRIPTION OF DRAWINGS

Those and other objects, features and advantages of the present invention will become more readily apparent from the following detailed description when taken in conjunction with the accompanying drawings wherein:

FIG. 1 is a main part enlarged cross-sectional view illustrating an inspection apparatus according to an embodiment of the present invention.

FIG. 2 is a main part enlarged cross-sectional view illustrating an inspection apparatus including a lock mechanism according to an embodiment of the present invention.

FIG. 3 is a partial plan view illustrating an arrangement state of chips of a semiconductor wafer.

FIG. 4 is a partial plan view illustrating a state in which the arrangement of the chips of the semiconductor wafer is overlapped with arrangement of spring pins and tester lands.

FIG. 5 is a partial plan view illustrating an embodiment of arrangement of the spring pins and the tester lands in a case where a wiring exclusion area exists.

FIG. 6 is a partial plan view illustrating a state in which the arrangement of the chips of the semiconductor wafer is overlapped with the embodiment of the arrangement of the spring pins and the tester lands in a case where the wiring exclusion area exists.

### DETAILED DESCRIPTION OF THE PREFERRED EMBODIMENTS

Hereinafter, an inspection apparatus according to embodiments of the present invention will be described with reference to the attached drawings.

An inspection apparatus according to the present invention is configured to include a prober mechanism having an XYZθ stage and the like supporting a semiconductor wafer as a plate under inspection, a tester adapted to perform an electrical test of the semiconductor wafer supported on the prober mechanism, and a probe assembly having a probe card adapted to apply test signals on the tester side via a tester head of the tester to respective electrodes of a plurality of chips formed on the semiconductor wafer. As such an inspection apparatus according to the present invention, every existing inspection apparatus having the above probe card can be used. That is, since the inspection apparatus according to the present invention is characterized by an electrical connecting structure between the tester and the probe card, the present invention can be applied to every inspection apparatus in which this electrical connecting structure between the tester and the probe card can be incorporated. Thus, in the present embodiment, the probe assembly and the peripheral structure are mainly described.

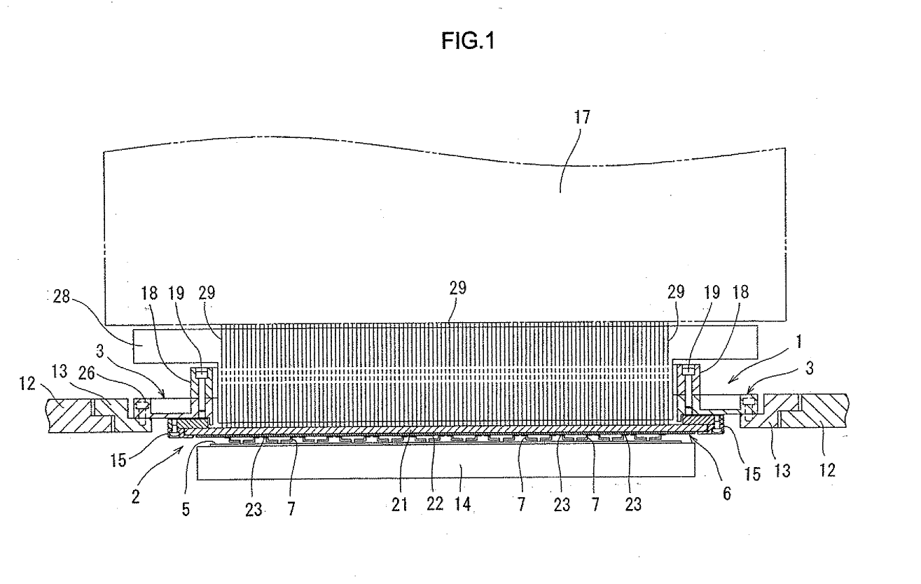

A probe assembly 1 of the present embodiment mainly includes a probe card 2 and a supporting member 3 supporting this probe card 2 as illustrated in FIG. 1.

The probe card 2 includes a disk-shaped probe substrate 6 corresponding to a disk-shaped semiconductor wafer 5 as a plate under inspection and a plurality of probes 7 provided on the lower side surface of the probe substrate 6 to electrically contact respective electrode pads (not shown) of the semiconductor wafer 5. It is to be noted that, since the plate under inspection is not limited to the disk-shaped semiconductor wafer 5 but may be in another shape, the probe substrate 6 is formed to correspond to the shape.

The probe substrate 6 is provided therein with wiring paths (not shown). One end of each wiring path is connected to an after-mentioned probe land 23 provided on the lower side surface of the probe substrate 6. The other end of each wiring path is connected to a tester land 35 provided on the upper side surface of the probe substrate 6. To each probe land 23 is fixed the probe 7. By doing so, each probe 7 is electrically connected to the corresponding probe land 23.

A specific configuration of the wiring paths of the probe substrate 6 will be described later. Meanwhile, the tester lands 35 on the upper side surface of the probe substrate 6 correspond to necessary signal, power, and GND pad electrodes in units of after-mentioned chip 10.

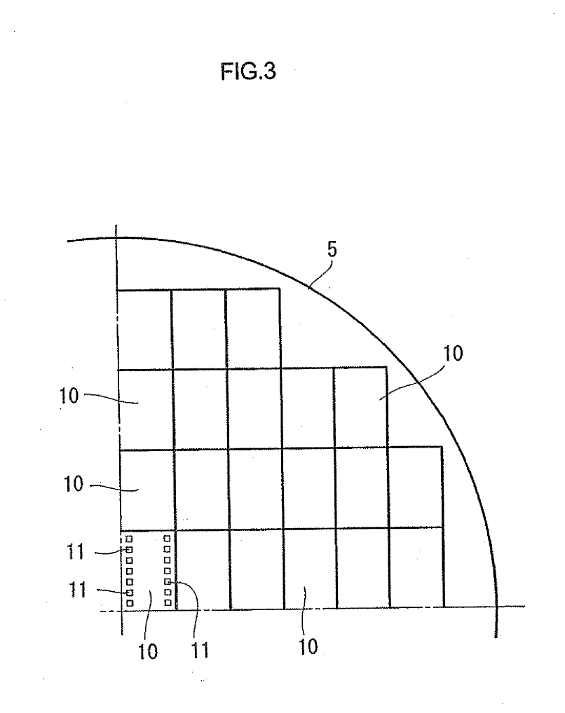

The probes 7 are arranged to correspond to each chip under inspection of the semiconductor wafer 5 as a plate under inspection. Specifically, as illustrated in FIG. 3, in a case the chips 10 of the semiconductor wafer 5 are arranged vertically and horizontally, and in a case where a plurality of electrode pads 11 are arranged at opposed side portions of each chip 10, the tip end portion of each probe 7 is arranged to align with each electrode pad 11 of each chip 10. The probes for necessary signal, power, and GND electrodes are arranged in units of chip 10. Each probe 7 is connected to the corresponding tester land 35 provided in an after-mentioned arrangement area 30 in units of chip under inspection.

The probe card 2 is supported on the supporting member 3 by an annular supporting plate 15, and the probe assembly 1 is held via a card holder 13 in an opening portion of a chassis 12 of a prober mechanism. By doing so, the probe card 2 is held so that the probes 7 may be opposed to the semiconductor wafer 5 on a chuck top 14 of an XYZθ stage. Also, to the upper surface of the supporting member 3 is attached an annular reinforcing member 18, which constitutes the probe assembly 1 together with the probe card 2 and the annular supporting plate 15.

On the upper side of the probe assembly 1 held in the card holder 13 is provided a tester head 17 electrically connected to a tester (not shown). The tester head 17 is turnably supported on the chassis 12 via a not-shown arm. The tester head 17 is supported by the arm and is fixed on the upper surface of the probe assembly 1 to cause wiring paths on the side of the tester head 17 to be electrically connected to wiring paths of the probe assembly 1. Accordingly, the wiring paths of a test circuit of the tester head 17 are electrically connected to the respective probes 7 of the probe card 2, and test signals from the tester are applied to electrodes of the respective chips of the semiconductor wafer 5.

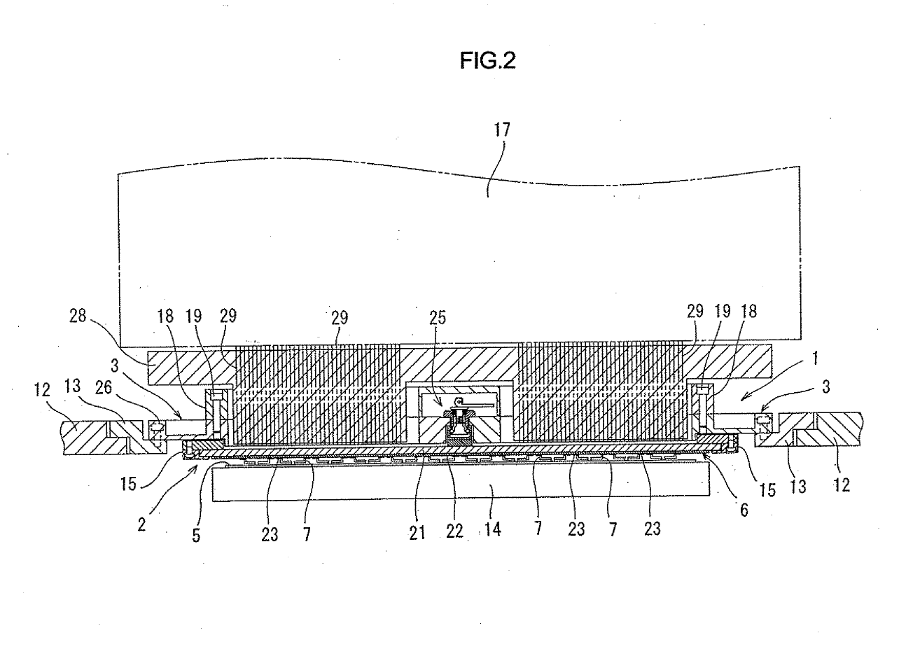

The supporting member 3 is a member for supporting the probe card 2 and an annular member in FIG. 1. As the supporting member 3, ones having various structures can be used. For example, the supporting member 3 in FIG. 2 includes a boss portion at the center, a plurality of spoke portions (not shown) extending radially from the boss portion, and an annular portion supported at each spoke portion.

The probe substrate 6 at least has an insulating plate 21 such as a ceramic and a wiring plate 22 fixed on the lower side surface of this insulating plate 21. On the upper side surface of the insulating plate 21 is provided the tester lands 35. The tester land 35 is an electrode that is brought into contact with an after-mentioned spring pin 29 as an electrical connecting portion on the side of the tester head 17.

The wiring plate 22 is a wiring board that connects the plurality of probes 7 of the probe substrate 6 to the tester lands 35 on the upper surface of the probe substrate 6. On the lower surface of the wiring plate 22 is provided the probe lands 23. The probes 7 are fixed on the probe lands 23 as described above. Wiring paths that electrically connect the tester lands 35 to the probe lands 23 in one-to-one relationship are provided in the insulating plate 21 and the wiring plate 22. A specific structure of the wiring plate 22 will be described later.

The probe card 2 and the supporting member 3 are fixed by the annular supporting plate 15 only at the circumference as in FIG. 1 in one case and are fixed at the center portion as well as at the circumference as in FIG. 2 in another case. In the case of FIG. 1, the probe card 2 is small in dimension and has only to be supported at the circumference in one case, and a vacuum adsorption method is used in another case. In the case of FIG. 2, a lock mechanism 25 is provided at the boss portion at the center of the supporting member 3. By this lock mechanism 25, the probe card 2 and the supporting member 3 are fixed to each other not only at the circumferential portion but also at the center portion. In the case where the lock mechanism 25 is provided, electrical connecting portions (spring pins 29) on the tester side cannot be provided at a part at which this lock mechanism 25 is located. Also, since a member corresponding to the lock mechanism 25 is provided on the upper side surface of the probe substrate 6, the center portion on the upper side surface of the probe substrate 6 becomes a wiring exclusion area in which no tester lands can be installed.

The probe assembly 1 including the probe card 2 and the supporting member 3 is mounted on the card holder 13 and is fixed by screw members 26.

On the lower side of the tester head 17 is provided a spring pin block 28 incorporating the plurality of spring pins 29. The arrangement positions of the spring pins 29 correspond to the tester lands arranged on the upper surface of the probe substrate 6. The tester head 17 incorporates a circuit board that tests semiconductor devices formed on the semiconductor wafer, and its test signals are applied from the circuit board via the spring pins 29 and the probes 7 to the pad electrodes of the respective devices. Contacts on both the ends of each spring pin 29 contact an electrode pad (not shown) of a wiring board on the side of the tester head 17 and the tester land 35 on the upper side surface of the probe substrate 6, respectively, by elastic expansion and contraction of the spring and electrically connect them. As the spring pin 29, a commercially available pogo pin or the like is used.

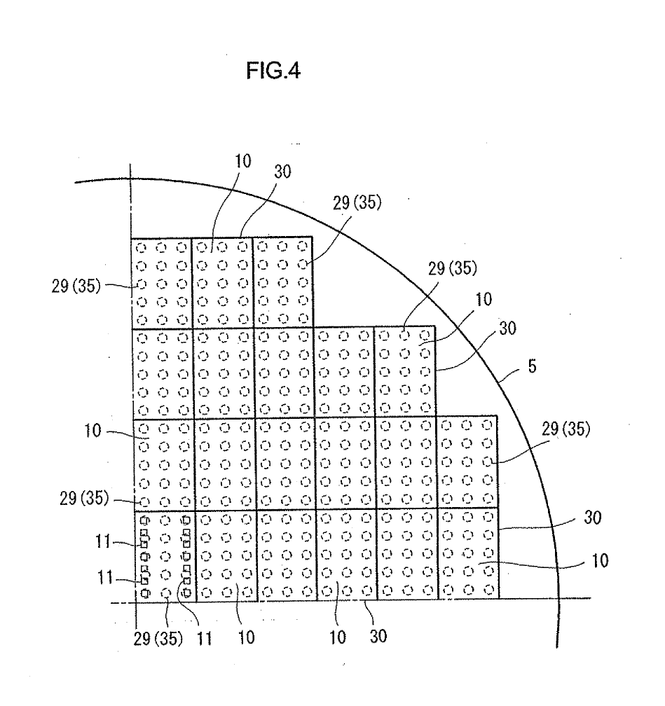

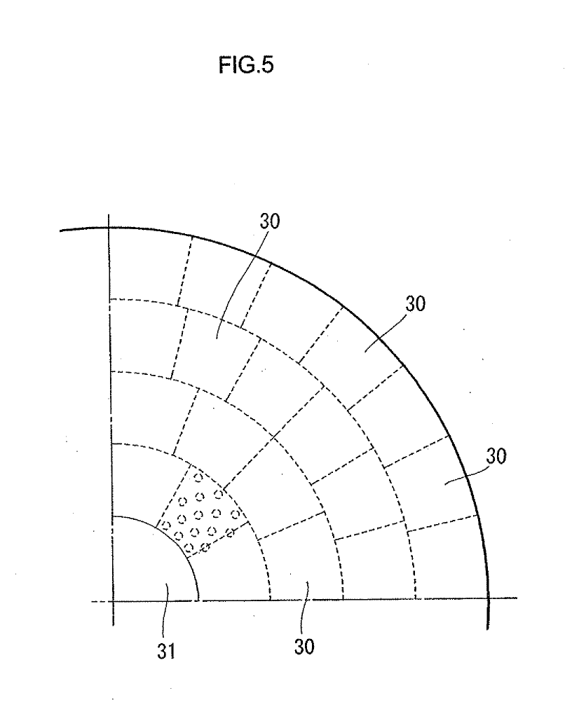

In the spring pin block 28, the plurality of spring pins 29 are arranged to constitute the plurality of arrangement areas 30 (see FIGS. 4 and 5) sectioned to correspond to the respective chips 10 under inspection. Also, the corresponding tester lands on the upper side surface of the probe substrate 6 are also arranged to constitute the plurality of same arrangement areas 30.

As for the arrangement of the plurality of arrangement areas 30, in a case where the probe assembly 1 has no lock mechanism 25 as in FIG. 1, the arrangement areas 30 can be arranged over the entire area of the semiconductor wafer 5 since no wiring exclusion area exists. In this case, the arrangement areas 30 are arranged at positions corresponding to the respective chips 10 arranged vertically and horizontally as illustrated in FIG. 4. However, the respective arrangement areas 30 may be arranged at positions displaced from the positions of the respective chips.

As for connection between the tester side and the probe substrate 6, when the number of the electrodes of the chip under inspection is equal to or smaller than the number of the electrical connecting portions (spring pins 29) on the tester side in units of chip, the chips under inspection and the arrangement areas 30 are made to correspond in one-to-one relationship as illustrated in FIG. 4. When the number of the electrodes of the chip under inspection is larger than the number of the electrical connecting portions (spring pins 29) on the tester side, the chips under inspection and the arrangement areas 30 are made to correspond in the ratio of A:A+α. That is, the size of the arrangement area 30 and the number of the spring pins 29 to be arranged are determined with reference to several kinds of standard chip sizes and electrode pad numbers, and in a case where the chip size on the semiconductor wafer to be tested and the number of electrode pads are increased, plural arrangement areas 30 can be made to correspond to plural chips along with this. For example, 3 (A+1) arrangement areas 30 can be made to correspond to 2 (A=2) chips. α is 2 or larger in some cases.

In each arrangement area 30, plural wiring paths such as power wires, GRID wires, and signal wires necessary to a test of one chip are arranged.

Also, when the probe assembly 1 has the lock mechanism 25 for connection between the probe card 2 and the supporting member 3 as in FIG. 2, the part becomes a wiring exclusion area 31 in which no arrangement areas 30 can be arranged, and thus the arrangement areas 30 will be arranged over the entire area of the semiconductor wafer 5 except this wiring exclusion area 31. In this case, the arrangement areas 30 may be arranged concentrically and annularly except in the wiring exclusion area 31 at the center as illustrated in FIG. 5 or may be arranged in another manner.

In each arrangement area 30 of the spring pin block 28 and the tester lands 35 illustrated in FIGS. 4 and 5, 15 spring pins 29 are connected to the corresponding tester lands 35, respectively. As for the spring pins 29, all or part of the spring pins 29 are used depending on the number of probes 7 as described above. While all of the spring pins 29 are electrically connected to the tester lands 35 of the probe substrate 6, only the tester lands 35 corresponding to the probes 7 to be used are connected to the probes 7 by the wiring paths in the wiring plate 22. However, spring pins 29 not in use need not be arranged in advance.

When multiple kinds of probe assemblies are to be manufactured, several kinds of arrangements of the tester lands on the upper side surface of the probe substrate can be standardized and shared.

In the wiring plate 22, the respective wiring paths from the plurality of probes 7 attached to the lower surface of the probe substrate 6 in units of chip to the plurality of tester lands 35 on the upper surface of the probe substrate 6 are provided to make them correspond so as to be shorter and equal in length. In a case where each arrangement area 30 and each chip 10 are aligned with each other as in FIG. 4, wiring paths connecting 14 out of 15 tester lands in the arrangement area 30 to the probes 7 corresponding to 14 electrode pads 11 on the chip 10 are provided in the inside of the insulating plate 21 and the wiring plate 22.

On the other hand, in a case where each arrangement area 30 and each chip 10 cannot be aligned with each other due to presence of the wiring exclusion area 31 as in FIG. 5, as many arrangement areas 30 as needed are arranged with use of the entire area of the wafer except the wiring exclusion area 31. In this case, the area that can be used as the arrangement areas 30 can be divided by the number of chips arranged on the wafer to become plural arrangement areas 30. In the wiring plate 22, wiring paths are connected to correspond to the adjacent chips in units of arrangement area 30.

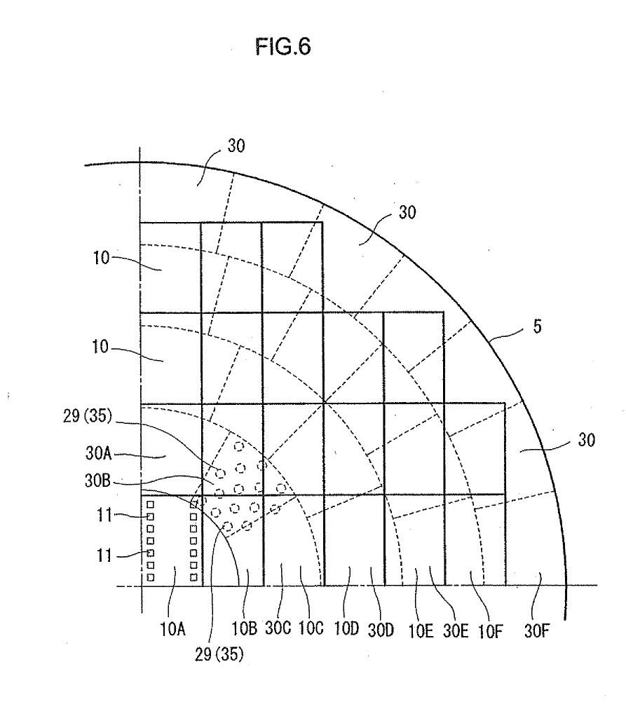

To describe this based on FIG. 6, to a chip 10A, out of the respective chips 10 of the semiconductor wafer 5, located in the wiring exclusion area 31, the tester lands 35 provided in an adjacent arrangement area 30A correspond. The probes 7 corresponding to the chip 10A and the tester lands 35 in the arrangement area 30A are connected in the wiring plate 22. Also, wires are provided so that the tester lands 35 in an arrangement area 30B and the probes 7 corresponding to the respective electrode pads 11 on a chip 103 may be connected. Similarly, wires are provided so that the tester lands 35 in arrangement areas 30C to 30F and the probes 7 corresponding to the respective electrode pads 11 on chips 10C to 10F may be connected. The other chips 10 and arrangement areas 30 are made to correspond similarly.

As described above, the wiring paths of the tester head 17 and the probe card 2 are arranged in units of chip 10 of the semiconductor wafer 5. That is, as an area in which the spring pins 29 and the tester lands 35 on the upper side surface of the probe substrate 6 are connected, the entire surface of the wafer area, not the outer circumference as in a conventional type, is used, and the connection is performed in units of arrangement area 30 corresponding to each chip. Consequently, it is possible to provide an inspection apparatus that can simplify connection wiring, reduce mutual noises among wires by shortening of respective wiring paths from the tester to the respective probes 7, and facilitate wires of equal length.

In a conventional spring pin block 28, since arrangement of signal, power, and ground wires is determined based on the tester, wires from tester lands 35 to probes 7 in a probe substrate 6 are long and complicated, and wires of equal length are not easy. On the other hand, in the present embodiment, the respective spring pins 29 of the spring pin block 28 and the tester lands 35 on the upper side surface of the probe substrate 6 are arranged based on the chip area, which simplifies connection wiring in the probe substrate 6, facilitates wires of equal length, and reduces design cost of the probe substrate.

The present invention is not limited to the above embodiments but can be altered or combined in various manners without departing from the spirit and scope thereof. As the electrical connecting portions of the tester head of the inspection apparatus, various contacts that can contact the tester lands such as probe members such as cantilever probes and rubber probes and connectors can be applied instead of the aforementioned spring pins.

In the claims:

1. An inspection apparatus at least comprising a probe card having a plurality of probes arranged to correspond to each chip under inspection of a semiconductor wafer and contacting a plurality of electrodes of each chip and a test head electrically connected to the respective probes of the probe card and applying test signals from a tester,
wherein a plurality of tester lands of a probe substrate electrically connected respectively to the plurality of probes and a plurality of electrical connecting portions on the tester side of the test head corresponding to the respective tester lands are arranged to constitute a plurality of arrangement areas sectioned to correspond to the respective chips under inspection, and
wherein the plurality of probes of the probe substrate are connected to the corresponding tester lands provided in the arrangement areas in units of chip under inspection.

2. The inspection apparatus according to claim 1, wherein, as for connection between the tester side and the probe substrate, when the number of the electrodes of the chip under inspection is equal to or smaller than the number of the electrical connecting portions on the tester side, the chips under inspection and the arrangement areas are made to correspond in one-to-one relationship, and when the number of the electrodes of the chip under inspection is larger than the number of the electrical connecting portions on the tester side, the chips under inspection and the arrangement areas are made to correspond in the ratio of A:A+α.

3. The inspection apparatus according to claim 1 or 2, wherein, when the probe card has a wiring exclusion area in which no arrangement areas can be arranged, connection between the tester side and the probe substrate is shifted to the arrangement area adjacent to the wiring exclusion area in units of chip under inspection.

4. The inspection apparatus according to claim 3, wherein the electrical connecting portions on the tester side are constituted by spring pins.

5. The inspection apparatus according to claim 2, wherein the electrical connecting portions on the tester side are constituted by spring pins.

6. The inspection apparatus according to claim 1, wherein, when the probe card has a wiring exclusion area in which no arrangement areas can be arranged, connection between the tester side and the probe substrate is shifted to the arrangement area adjacent to the wiring exclusion area in units of chip under inspection.
